(19) United States
(12) Patent Application Publication
(10) Pub. No.: US 2015/0194565 A1
(43) Pub. Date: Jul. 9, 2015

(54) Solid State Light Production Using Flexible Grouping Of LEDs

(71) Applicant: KLA-Tencor Corporation, Milpitas, CA (US)

(72) Inventors: Richard W. Solarz, Danville, CA (US); David Oak, San Francisco, CA (US)

(21) Appl. No.: 14/589,859

(22) Filed: Jan. 5, 2015

Related U.S. Application Data
(60) Provisional application No. 61/924,361, filed on Jan. 7, 2014.

(51) Int. Cl. H01L 33/00; B07C 5/342

(52) U.S. Cl. CPC H01L 33/005; B07C 5/342

(57) ABSTRACT

Solid state lighting devices (e.g., lamps and fixtures) are produced using unbinned/uncharacterized LEDs from an entire LED production “cloud” by way of sequentially measuring light emitted from the unbinned LEDs, and then assigning/placing each unbinned LED immediately into an associated LED product group (e.g., directly onto a PCB that forms part of the final lamp/fixture). The group assignment for each LED is based on how its measured light matches with other LEDs based on flexible group characteristics, which are generated in accordance with user-defined parameters, whereby each LED is placed in a product group such that light collectively generated by the LEDs of each product group complies with the user-defined parameters. The flexible group characteristics are also adjusted in real time (i.e., as batch-related characteristics of the LED “cloud” are acquired by way of the sequential testing), whereby the LED assignment process is modified for each LED batch.

### RELATED APPLICATIONS

This application claims priority to U.S. Provisional Patent Application 61/924,361, entitled “Intelligent Addition of LEDs” filed Jan. 7, 2014.

### FIELD OF THE INVENTION

This invention relates to LED lights, and more particularly to methods for producing solid state lighting devices that generate mixed (e.g., white) light by way of light generated from multiple LEDs.

### BACKGROUND OF THE INVENTION

As the solid state lighting industry matures, it has evolved into essentially three product types for solid state lighting: HBLEDs (high brightness LEDs) MBLEDs, (medium brightness), and COB (chip on board). It is believed that the fastest growth and largest market share among these three products will be MBLEDs which can be loosely defined as LEDs which operate from 25 to 150 milliamperes (ma) of drive current (although MBLEDs are constantly evolving toward higher drive currents), generally operate without a silicone dome lens for light extraction, and are produced in simple architectures which typically allow them to be produced for five to seven cents per die, as compared to roughly 50 cents for producing the higher power HBLEDs.

MBLEDs are best utilized in white light systems that require distributed light, an example being troffer lighting. Troffer lighting can be exemplified by the approximately two foot by four foot ceiling lights typically populating offices and retail stores. Troffer lights, which today represent 37% of the total lighting market, are typically populated by four foot long linear fluorescent lights which produce 5000 lumens apiece. MBLED lights, which typically include multiple MBLED chips mounted on an elongated carrier board, currently have higher efficacy than linear fluorescent lights and have much longer lifetimes, and are therefore expected to rapidly displace fluorescent lights in troffers and other lighting sectors. To produce the 5000 lumens generated by conventional linear fluorescent troffer lights, approximately 250 MBLED chips, each producing 20 lumens of light each, are assembled on a carrier board and activated simultaneously.

The illumination generated by any light source is measured by the quantity of illumination (output/flux, light level/intensity and brightness) and quality of illumination (i.e., glare, uniformity and color rendition).

Quantity of illumination is described in terms of output/flux, light level and brightness. The most common measure of light output (or luminous flux) is the lumen, and most light sources (i.e., lamps/bulbs and sometimes fixtures) are labeled with an output rating in lumens. For example, a T12 40-watt fluorescent lamp may have a rating of 3050 lumens. Illuminance is the light intensity (level) measured on a plane at a specific location. Illuminance is measured in footcandles, which are workplane lumens per square foot. Using simple arithmetic and manufacturers' photometric data, you can predict illuminance for a defined space.

In addition to light intensity, color quality is a primary consideration for solid state lighting. Lighting must produce a consistent Color Rendering Index (CRI) and Correlated Color Temperature (CCT) to be accepted in the market. The CRI scale is used to compare the effect of a light source on the color appearance of its surroundings. A scale of 0 to 100 defines the CRI. A higher CRI means better color rendering, or less color shift. CRIs in the range of 75-100 are considered excellent, while 65-75 are good. The range of 55-65 is fair, and 0-55 is poor. Under higher CRI sources, surface colors appear brighter, improving the aesthetics of the space. Sometimes, higher CRI sources create the illusion of higher illuminance levels. Another characteristic of a light source is the color temperature. This is a measurement of “warmth” or “coolness” provided by the lamp. People usually prefer a warmer source in lower illuminance areas, such as dining areas and living rooms, and a cooler source in higher illuminance areas, such as grocery stores. Color temperature refers to the color of a blackbody radiator at a given absolute temperature, expressed in Kelvins. A blackbody radiator changes color as its temperature increases (first to red, then to orange, yellow, and finally bluish white at the highest temperature. A “warm” color light source actually has a lower color temperature. For example, a cool-white fluorescent lamp appears bluish in color with a color temperature of around 4100 K. A warmer fluorescent lamp appears more yellowish with a color temperature around 3000 K.

Today, color consistency is achieved in MBLED products by the use of “bin mixing” (also referred to as “kitting”). The bin mixing process generally begins with the light device manufacturer ordering “bins” of MBLEDs (or other LED types) from an LED manufacturer. A bin is defined by a given manufacturer as any grouping of LEDs which have a range of color coordinates, range of flux at some specified current, and a range of forward voltages. The color coordinates may be in the x-, y-coordinate system, the u′-, v′-coordinate system or any related coordinate system but are most typically given in the x-, y-coordinate system by each LED manufacturer. The ranges of the two color coordinates and the forward voltage and flux then define a specific bin. The two color coordinate ranges for x-, and y-clearly will define a quadrilateral shape within the x-, y-coordinate system with the vertices given by a predefined (xmin, ymin), (xmin, ymax), (xmax, ymin) and (xmax, ymax). After final fabrication each LED manufacturer characterizes the LEDSs and places them into a given “bin” defined by the color quadrilateral, forward voltage range and flux range. Clearly the rationale behind binning is to collect LEDs of similar and well defined properties in order to aid the customer, the lighting integrator who places the LEDs into a lighting fixture (enclosure, optics, power supply, and heat sink) for sale to consumers in the end market.

Generally one can visualized a collection of bins grouped around a specific target color coordinated temperature (CCT) on the black body curve (BBC) within the color coordinate system. This grouping can be as large as seven or more MacAdam ellipses and roughly describes the range of colors produced by many manufacturers during a production run aimed at yielding LEDs near the target CCT. A manufacturing run can then, typically, result in roughly 16 color bins (sometimes more than 16) surrounding the target CCT with each bin being roughly 3 ellipses in extant. Within each of the 16 color bins there are additional bins in flux and voltage. Lighting integrators most often prefer to order then central four bins, those having one vertex touching upon the CCT located on the black body curve. FIG. 3 illustrates a typical bin structure for a manufacturer in color space and also highlights the four center “opposed” bins. These four central bins are often referred to as “opposed” bins due to the fact that if LEDs are selected one each from each of the four bins their average color will be close to the target due to the balancing of the deviations from the CCT above, below, to the left, and to the right of the target CCT. Using this technique of “color mixing” the lighting integrator is then able to produce lighting which is “white” (on the BBC) by using a mixture of LEDs which are all generally somewhat above, below, and to the left and right of the target CCT on the BBC. Using a large number of LEDs in each of these bins the integrator can then produce a large number of lighting fixtures which “match”, that is appear to the majority of the human observers to be of the same color or CCT. Alternately, a “kit” or grouping of bins using a collection of die chosen from opposed bins which do not share the CCT at one vertex but rather are separated in color space from the CCT by equally opposed offsets can also be used.

It should be noted that the averaging of multiples of LEDs of different colors by the human eye is dependent upon the design of the lighting fixture, and in particular the optics placed within the fixture to collect and deliver light to a given viewing point from multiple LEDs within the fixture, the spacing of the LEDs within the fixture, and a variety of other factors. For example, if the viewer of a lighting fixture is able to spatially fixate and separate two LEDS within the fixture being viewed, the viewer does not average the two LEDs colors but is able to register any color difference that they may possess. These factors give rise to a large number of patents on “light-mixing” techniques and apparatus such as U.S. Pat. No. 8,882,290 B2 (Nov. 11, 2014) and patents cited therein. We also note that the concept of mixing is described in U.S. Patent US 2013/0082622 A1 by Tien, Chien, and Chiang. These patents all describe methods of generally selecting LEDs from pre-determined opposed bins (generally referred to as “mixing” or “kitting”) and additional optical design techniques to homogenize the light from a variety of LEDs into a given field of view.

The disadvantage of the above procedures are primarily poor use of manufactured die or low yield and other factors as well. Regarding use of manufacturing die, roughly only half the die resulting from a given manufacturing run will fall into the most highly sought after four central opposing bins. Thus roughly half of the LEDs that are manufactured are not used to fabricate white lighting, the primary market for LEDs, and at least they are not used to fabricate quality lighting, lighting defined as matching within two step MacAdam ellipses. Secondary concerns regarding the current binning process is that some manufacturers may charge a premium price for the central bins and, importantly, may experience delays in shipping the central bins if the manufacturing line is unable to replenish depleted stock.

Elaborating on these factors the various bins are not produced in uniform quantity during any given production run. Typical production runs today may produce 20% each into three of the target quadrants but only 5% into the fourth. Thus, furnishing a manufacturer with the four quadrants in equal number, as required by today's practice of mixing, results in only four quadrants of five percent or 20% of the total production run being sold into the mixing application. The manufacturer then schedules subsequent production runs to refill the depleted (initially) 5% quadrant bin and this results inevitably in shipping delays to future or current lighting customers. In sum, today's mixing procedure is a cost, yield, and schedule driver of the great importance within the MBLED lighting business.

What is needed is system and method for assembling LED light groups that avoids the high cost and waste associated with conventional “binning” methods.

### SUMMARY OF THE INVENTION

The present invention is directed to an improved method that eliminates the process of LED manufacturer binning, the placing of characterized LED into bins of predetermined color coordinates (and fluxes and forward voltages) and to replace it instead with the method and equipment for flexible/adjustable grouping at the lighting integrator. In our process the LED manufacturer does not bin the LEDs, and instead ships the entire seven-MacAdam-ellipse-LED production, often referred to in the industry as a “production cloud” or simply a “cloud”, of LEDs from a given CCT run. State of the art today at top tier manufacturers currently produce well over 99 percent of the LED units produced in a given run to within seven ellipses of the targeted CCT. The “flexible grouping” or “adjustable grouping” process of the present invention uses all of the unbinned LED units produced and shipped by the LED manufacturer. The task of achieving lamp color uniformity from this shipment of seven ellipse LEDs is placed upon the luminaire (device) manufacturer, who performs the “flexible grouping” or “adjustable grouping” process.

According to an embodiment of the present invention, a system for producing solid state lighting devices (e.g., lamps and fixtures) coordinates testing and grouping of LEDs into associated product groups in real time (i.e., the LEDs are assigned to groups immediately after being analyzed by a tester). The grouping process uses flexible group target characteristics that facilitate assigning essentially all “unbinned” LEDs from a manufacturer's LED fabrication run to an associated solid state lighting device based on their measured light characteristics immediately after these characteristics are determined during testing. In the disclosed embodiment, the system includes an LED tester configured to apply test conditions to an LED-under-test and to measure light emitted from the LED-under-test under the test conditions, an LED product group assembler, transport mechanisms for sequentially transporting the unbinned LED units to the LED tester, and from the LED tester to the LED group assembler, and a system controller configured to implement a group generator. According to an aspect of the invention, the group generator determines initial flexible group target characteristics by way of user-defined parameters (e.g., color point, matching accuracy, and brightness/flux, which define the mixed light characteristics of a to-be-produced solid state lighting device). The group generator also assigns, immediately after testing (i.e., in real time), each unbinned LED unit to an associated said LED product group in accordance with LED light measurements received from the LED tester for each unbinned LED unit, where the assignment is performed such that the LED product group to which the LED is assigned complies with the generated flexible group characteristics. In addition, the group generator updates the flexible group characteristics in accordance with said LED light measurements.

### BRIEF DESCRIPTION OF THE DRAWINGS

These and other features, aspects and advantages of the present invention will become better understood with regard to the following description, appended claims, and accompanying drawings, where:

FIG. 1 illustrates a simplified LED assembling system according to an embodiment of the present invention;

FIG. 2 illustrates an exemplary hot test system for testing LEDs that is utilized in the system of FIG. 1 accordance with an embodiment of the present invention; and

FIG. 3 illustrates a typical bin structure for a manufacturer in color space and also highlights the four center “opposed” bins.

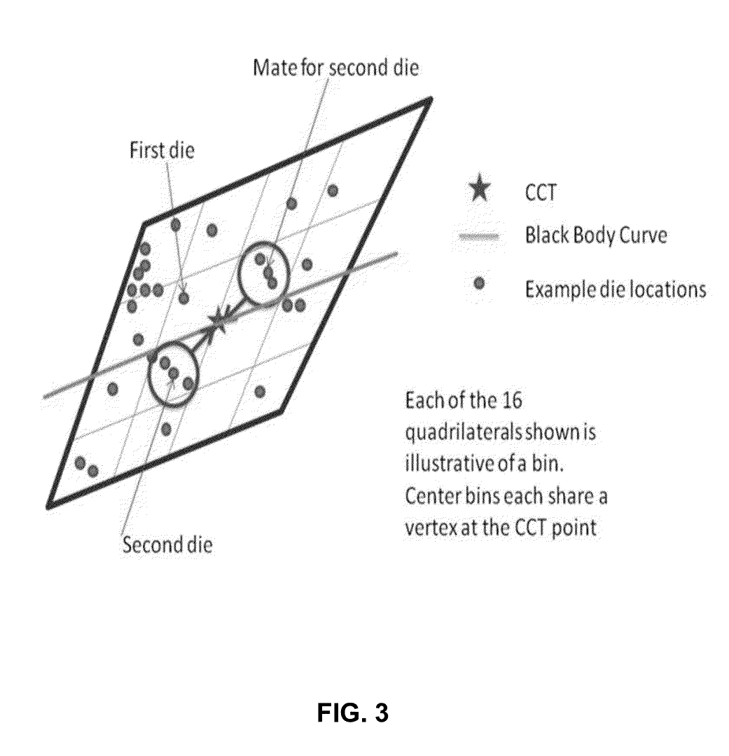

### DETAILED DESCRIPTION OF THE DRAWINGS

The present invention relates to an improvement in the production of solid state lighting devices that generate mixed (e.g., white) light. The following description is presented to enable one of ordinary skill in the art to make and use the invention as provided in the context of a particular application and its requirements. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

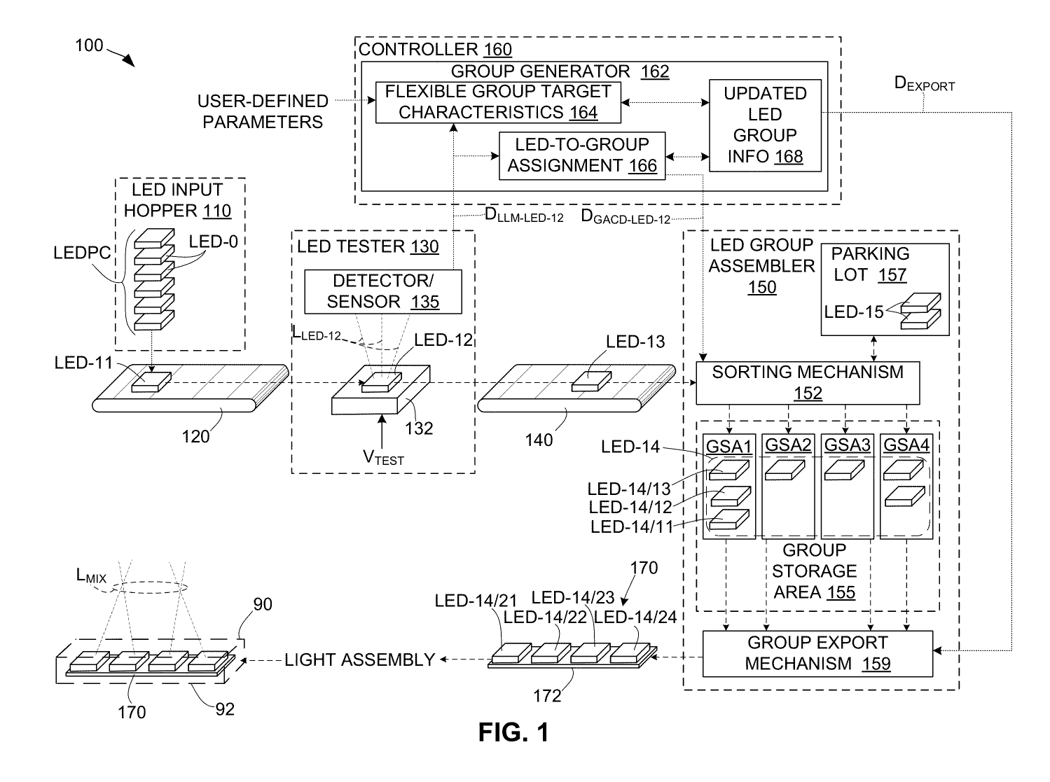

FIG. 1 shows a system 100 for producing solid state lighting devices 90 (e.g., lamps and fixtures) using a production cloud LEDPC including unbinned light emitting diode (LED) units (e.g., LED-0). As used herein the phrase “production cloud” is defined as a manufacturer's LED production batch that varies in color space about a given correlated color temperature (CCT) by as many as 7 step MacAdam ellipses and no less than 5 step ellipses. System 100 utilizes the subsystems and methods shown in FIG. 1 and described below to produce solid state lighting devices 90 such that, as illustrated at the lower left portion of FIG. 1, each solid state lighting device 90 includes an LED product group 170 disposed in an optional housing 92, where each LED product group 170 includes multiple unbinned LED units operably connected by way of a board (e.g., as indicated in the lower center of FIG. 1, LED-14/21, LED-14/22, LED-14/23 and LED-14/24 are mounted on a printed circuit board (PCB) 172). The unbinned LED units of each LED product group are selected and arranged on a board such that, during operation (i.e., when power is applied by way of PCB 172 to device 90), the unbinned LED units LED-14/21 to LED-14/24 collectively generate mixed light L_{MIX} that conforms with the user-defined parameters (e.g., color point, matching accuracy, brightness or flux), and has a color uniformity of three MacAdam ellipses or less.

According to an embodiment, system 100 is operated by a device (luminaire) manufacturer, who provides user-defined parameters that define the characteristics of LED product groups 170. The device manufacturer is uniquely aware of which products (solid state lighting devices) he intends to place the shipped LEDs. Each product is characterized by a given spacing of LEDs on a given board, and by an optical design (user-defined parameters, such as color point, matching accuracy, brightness or flux) that will predetermine the population of die within a board over which the human observers eye will average the color coordinate output. Thus, the device manufacturer will know if a given product will need to average over say 32, 16, or 8, for example, LEDs each in order to produce a color apparent to the observer from a given fixture or lamp. The device manufacturer thus is faced with the task of selecting from among the seven ellipse batch or cloud of received MBLEDs to produce uniform color from his products. The device manufacturer also can uniquely set the target uniformity coordinates or other target parameters such as minimum lumen values or consistent forward voltages, color point, matching accuracy, brightness or flux. One color uniformity target can be, for example, one to one and one and half ellipses, or as much as three or four ellipses, the latter being the practice in the industry today. In contrast, with today's mixing practice, the ability to set the final product uniformity to smaller and smaller ellipses is gated by the LED manufacturer's willingness to characterize and inventory smaller and smaller bins at smaller yields, greater cost, and increased restocking times. The device manufacturer also knows how many lighting fixtures he is producing for a given job, how many lights will be placed at a given construction site, for example, and therefore how many lights need to match within two steps of each other. These lights need not match this tightly with those placed at a manufacturing site at another location. The second location luminaires need to match within two steps of each other but as a group can be different by some degree from the grouping at the first site. As indicated in FIG. 1, these various target parameters are entered into controller 160 as USER-DEFINED PARAMETERS.

According to the illustrated embodiment, system 100 generally includes an LED input hopper 110, a first LED transport mechanism 120, an LED tester 130, a second LED transport mechanism 140, an LED group assembler 150, and a controller 160. In this arrangement, LED input hopper 110, first LED transport mechanism 120 and second LED transport mechanism 140 serve to sequentially transport unbinned LED units to LED tester 130, and from LED tester 130 to LED group assembler 150. In one embodiment, input hopper 110 receives unbinned LED units (e.g., LED-0) in the form of rough buckets or a full cloud (not 1/16^{th} reels), and are loaded with a bowl feeder. First LED transport mechanism 120, which is illustrated as a conveyor for illustrative purposes only, and may be implemented using any suitable transfer mechanism, sequentially transfers unbinned LED units (e.g., LED-11) to LED tester 130. LED tester 130 is configured to apply test conditions (e.g., test voltage V_{TEST} and heat to generate test temperature conditions) to each unbinned LED unit mounted thereon (i.e., the “LED-under-test”, e.g., LED-12 in FIG. 1), and includes a detector/sensor 135 configured and positioned to measure light L_{LED-12} emitted from the LED-under-test under the applied test conditions. In one embodiment, LED tester 130 includes a mechanism for applying heat to the LED-under-test to prepare the temperature of the junction of the LED and the phosphor of the LED by means of hot air soaking of the junction and laser excitation of the phosphor respectively to selected test temperatures. LED tester 130 transmits in real time LED light measurements for each LED-under-test (e.g., LED light measurement D_{LLM-LED-12}, which includes data quantifying measured light L_{LED-12} generated by LED-12, is transmitted to controller 160). After testing, each unbinned LED unit (e.g., LED-13) is passed from LED tester 130 to LED group assembler 150 by way of second LED transport mechanism 140. LED product group assembler 150 generally includes a sorting mechanism 152 for placing each tested unbinned LED unit received from LED transport mechanism 140 either into an associated product group configuration (e.g., group storage areas 155, which in the illustrated example include areas GSA1, GSA2, GSA3 and GSA4) or into a holding area (“parking lot”) 157, which is discussed below. In a presently preferred embodiment, placing each tested unbinned LED unit (e.g., LED-14) involves placement onto a board (e.g., PCB 172, shown in the center bottom of FIG. 1) for direct insertion into a solid state lighting device. As set forth below, placement of each tested unbinned LED unit is performed in accordance with group assembly control data such that each product group configuration includes only unbinned LED units assigned to a single product group 170. For example, group area GSA1 includes LEDs LED-14/11, LED-14/12 and LED-14/13, which are mounted onto a single PCB and subsequently passed as a group to group export mechanism 159 for transport to an external light assembly mechanism (not shown) for final processing into a solid state lighting device.

Referring to the upper portion of FIG. 1, controller 160 is implemented using a processor or other computing circuit that is programmed using known techniques to perform various functions that control the operations of system 100 including a group generator function 162. According to an embodiment of the present invention, controller 160 is configured to perform various functions associated with the formation of product groups 170, including generating flexible group target characteristics in accordance with the input USER-DEFINED PARAMETER data (indicated at box 164), assigning the unbinned LED units to product groups (LED-to-group box 166), and generating/storing/updating LED product group information (box 168). According to an aspect of the invention, the assignment of each unbinned LED unit (e.g., LED-12) to an associated LED product group 170 is performed in accordance with that LED's LED light measurement data (e.g., light measurement data D_{LLM-LED-12}), which is received from LED tester 130, and also in accordance with existing group information such that the LED product group to which each LED is assigned complies with the flexible group characteristics after the LED assignment is completed. For example, LED-12 is assigned to the product group shown in area GSA1 if the addition of LED-12 to the previously formed subgroup including LED-14/11 to LED-14/13 would generate an LED product group that complies with the flexible group characteristics. If not, then LED-12 is assigned one of the other groups (e.g., the product group shown in area GSA2), but again only if the assignment does not contradict the flexible group characteristics, or temporarily assigned to parking lot 157. According to an aspect of the invention that is discussed in further detail below, after assigning each unbinned LED to an associated LED product group, flexible group target characteristics section 164 updates (modifies) the flexible group characteristics in real time in accordance with the latest LED light measurements (e.g., data D_{LLM-LED-12}).

According to an embodiment, controller 160 is further configured (e.g., by way of LED-to-group routine 166) to generate group assembly control data for each unbinned LED unit based on its group assignment, and to transmit the group assembly control data to LED group assembler 150. For example, after LED-12 is assigned one of the group configurations (e.g., the product group configuration residing in area GSA1), group assembly control data D_{GACD-LED-12} is transmitted to sorting mechanism 152, whereby when LED-12 arrives at LED group assembler 150 by way of transport mechanism 140, it is immediately placed into area GSA1. In one embodiment, sorting mechanism 152 includes a mechanical arm or other suitable mechanism for placing unbinned LED units LED-14 directly onto PCBs that can, when the entire product group is completed, be directly inserted into a solid state lighting device (e.g., a lamp).

In one embodiment, the group assembly control data for one or more unbinned LED units may designate parking lot (holding area) 157 when assignment to any of the existing product group configurations would fails to comply with said flexible group characteristics. For example, if LED-12 has light characteristics such that adding LED-12 to any of the existing product group configurations (i.e., those in areas GSA1 to GSA4) would cause those product group configurations to violate the flexible group characteristics, then group assembly control data D_{GACD-LED-12} designates LED-12 for temporary assignment to parking lot 157, and sorting mechanism 152 places LED-12 in parking lot 157 when it arrives at LED group assembler 150. In one embodiment, parking lot 157 is used as a holding position to delay the placement of any given LED into a group configuration based on a decision that the certainty of assigning it to a subgroup can be better made later in the manufacturing run.

In one embodiment, the updated LED group information (box 168) is utilized to generate completed group export commands D_{EXPORT} when any of the product group configuration (i.e., those in areas GSA1 to GSA4) are “complete” (i.e., include the designated number of LEDs that collectively generate the desired mixed light). For example, if the assignment of LED-12 to the product group configuration residing in area GSA1 “completes” that group, then a completed group export command D_{EXPORT} is transmitted to group export mechanism 159, thus causing group export mechanism 159 to remove the product group configuration from area GSA1, thus making area GSA1 available for a “new” group configuration.

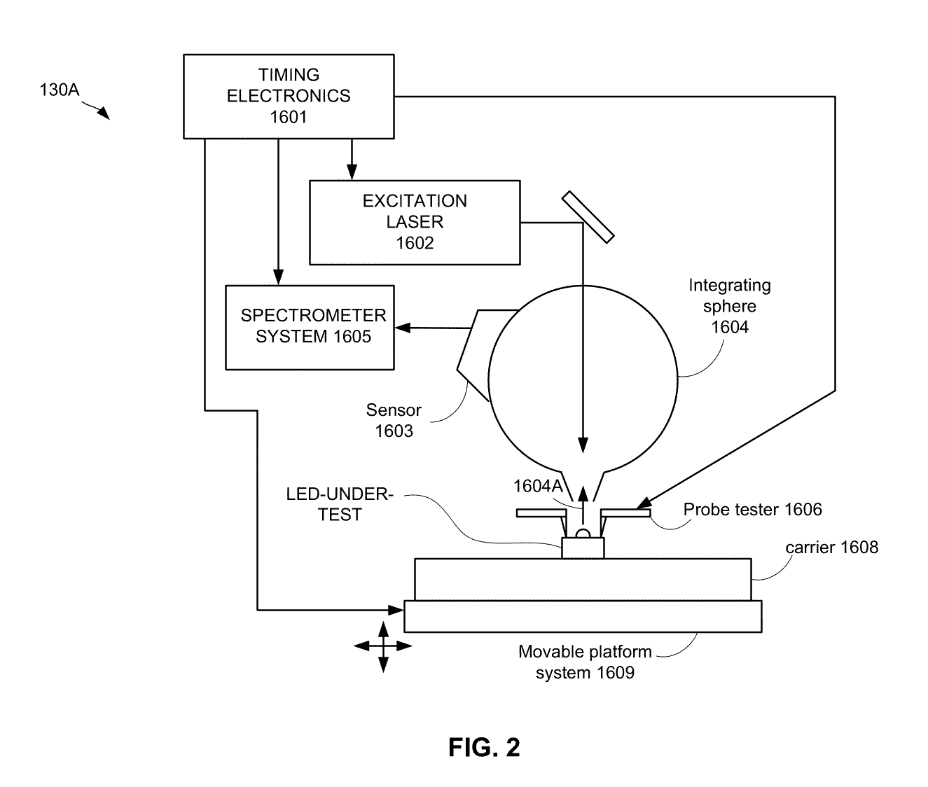

FIG. 2 illustrates an exemplary hot test system 130A that is utilized in place of LED tester 130 (FIG. 1) in a presently preferred embodiment. The purpose of hot testing is to bring each LED-under-test to a temperature mimicking the operating conditions of the LEDs within a lamp fixture prior to the characterization measurement. As known in the art, MBLEDs and HBLEDs include a InGaN film, a phosphor layer formed on the InGaN film, and (in the case of HBLEDs only) a lens formed over the phosphor layer and the InGaN film. Hot test system 130A utilizes an excitation laser 1602 to excite portions of the phosphor or phosphor layer of an LED-under-test (e.g., the unbinned LED units described above with reference to FIG. 1), and to establish an appropriate temperature gradient therein. A probe tester 1606 provides current to the LED-under-test and can also be used to bring the InGaN film to 85° C. In one embodiment, excitation laser 1602 and probe tester 1606 are controlled by timing electronics 1601 to provide the appropriate time periods of laser excitation and current application. An integrating sphere 1604 (also known in the industry as Ulbricht spheres), having an interior surface that scatters light evenly over all angles, facilitates the collection of light from the LED-under-test after laser excitation and current application. Integrating sphere 1604 is essentially an optical element consisting of a hollow spherical cavity with small holes for entrance and exit ports. In one embodiment of integrating sphere 1604, the entrance port can include a collar 1604A angled to provide a close fit around the lens of the LED-under-test during hot testing, thereby ensuring that extraneous light to the LED-under-test is not collected and ensuring that all LED-under-test emitted light is collected. Collar 1604A can include a high angle reflection optic that allows integrating sphere 1604 to collect light from the LED-under-test at angles from 10° to 170°. In one embodiment (shown in FIG. 2), the light beam from excitation laser 1602 can be directed through integrating sphere 1604 to the LED-under-test. In other embodiments, the light beam can be directed obliquely onto the LED-under-test without passing through integrating sphere 1604. Additional details regarding system 130A and the associated hot test methodology are provided in co-owned and co-pending U.S. patent application Ser. No. 13/673,947 entitled “HIGH THROUGHPUT HOT TESTING METHOD AND SYSTEM FOR HIGH-BRIGHTNESS LIGHT-EMITTING DIODES” filed Nov. 9, 2012, which is incorporated herein by reference in its entirety.

Additional aspects and alternative features of the present invention will now be described.

As discussed above, “flexible grouping (also referred to as “adjustable grouping” herein) the manufacturer must first first determine the “averaging length or area” within his lighting product (based upon LED spacing and lighting optics) as well as his targeted lighting uniformity. He then has the option of using “adjustable grouping” to either populate the boards directly with pick and place tools using the “adjustable grouping” process (e.g., by way of sorting mechanism 152, FIG. 1), or he may choose to populate reels which are subsequently fed into pick and place tools for board population.

The flexible (adjustable) grouping process can be described as a decision not to place individual LEDs into predetermined bins with predetermined parameters but rather a decision to place a selected LED into a preexisting population or group of LEDs in which the selected LED “best benefits” among the existing population sets insofar as bringing its characteristics toward the desired target properties, for example color coordinates. Imagine a process in which four boards are to be populated by a seven ellipse production run of LEDs and the targeted color uniformity is one and one half ellipses. Imagine four characterization channels or spectrometers in parallel which are used to feed a pick and place tool which in turn will populate in parallel four boards (or, equivalently, four reels). Each characterization channel first characterizes one MBLED each and each MBLED is used to populate a separate board from amongst four boards (board A, B, C, or D or equivalently four separate reels). The software in the characterization tooling keeps a running inventory of the resultant color coordinate (and/or forward voltage and flux) of the LED placed onto boards A through D. Four new die are then characterized in each spectrometer channel and their characteristics noted. The tooling software then decides which MBLED to add to which board.

Let each partially populated board have a color coordinate which is the average in xp- and yp- of the color coordinates of the MBLEDs already placed on that board. Thus in a very simple example xp=(x1+x2)/2 and so on when there are already two MBLED per board. This color coordinate will always be different from the target coordinate X- and Y- by an amount Δx=X−xp and Δy=Y−yp and the length of the deviation vector for that board is then defined as DEV=SQRT (Δx*Δx+Δy*Δy).

The decision to place subsequent MBLEDs onto each board may be made in a number of ways but one example would be to make this decision based upon any of a number of algorithms which minimizes the sum length of the four running total deviation vectors DEVa, DEVb, DEVc, and DEVd prior to each placement. The goal in the placements is to arrive at a predefined deviation minimum from a target coordinate for all four boards after the placement of a number of die equal to the number of die which are optically averaged by the human eye in a given lamp design. If the number of die averaged by the human eye in a given lamp design is for example 16 (we will define this as the “averaging number”), the goal may be to have the deviation vector for each board, after sixteen die, to be less than the length of one or two MacAdam ellipses within that region of the CIE color coordinate diagram.

The average color coordinate for a given production cloud of LEDs generally will not lie exactly at the target CCT on the BBC. The average will always differ by some measurable amount from this target value. The adjustable/flexible grouping process will have the ability to adjust the target coordinates for each manufacturing run based upon its ability to calculate the average color coordinate for the cloud as it populates boards or tapes in real time. As part of the process of deciding which LEDs to add to which boards or tapes, the adjustable grouping tool will revise the target coordinate from the CCT on the BBC to a value closer to the average coordinates of all LEDs in the cloud by entering a new target coordinate as this information is discerned from the collection of real-time binned LEDs. The groupings are thus real time adjustable as to their final target characteristics, they are not predetermined as is the case in the current art. Any of a number of algorithms may be used to determine how accurately the “true” resulting average from a cloud will be at any given time during a production run. For example, early on it may be that in the parallel construction of four boards, one LED is encountered which can be described as an “outlier”. Namely its coordinates may be several standard deviations different from those of the other 15. The adjustable grouping tool or apparatus will then place this particular LED into a “parking lot” to be retrieved at a later time if a compatible LED product group is identified, or discarded (eliminated from use) if determined that the LED unit is unsuitable for assignment to any LED product group. In one embodiment, any LED placed in a parking lot will not have its coordinates and other properties entered into the real time calculation of flexible group target characteristics. Only those die which are placed onto boards or reels have their data entered into the continuously adjusted target features.

In utilizing the entire seven ellipse production run of MBLEDs to produce boards which lie within one or two ellipses a goal is to have board yield within this goal as close to 100% as possible and to have die utilization as close to 100% as possible. To accomplish these objectives an algorithm may use additional constraints. One constraint may be to reject an “outlier”, namely to reject a MBLED which has just been characterized (but not yet placed) which the algorithm believes will result in the final board likely not being within the targeted coordinate space. Simulations have shown that rejections of die which are as much as seven ellipses from the target coordinate are likely to occur if they are late in the placement process, that is if they are among the last HBLED placed just before reaching the averaging number for that board. Clearly an outlier can be compensated if it is position in color space is known early in the addition process but not if it is among the last die or two or three to be added in the addition process.

To restate, to increase die utilization it is recognized that the average x- and y-color coordinate position may not be on the black body curve. Adjusting the flexible grouping assignment process to achieve final colors which deviate significantly from that of the average population then clearly reduces utilization. Statistically it is clear that generally after 30 or 40 die are characterized from a new incoming production run, the average deviation of the entire run from the blackbody target temperature is well known in x- and y-, in fact it is known to within a fraction of a one step MacAdam ellipse. The algorithm may then adjust the “target” color coordinates for all boards as the addition is proceeding. This is a productive course to pursue so long as the resultant Duv (deviation from the black body curve) remains within the Duv tolerance values of Table 1 of ANSI—NEMA-ANSLG C78.377-2008 or more stringent future standards.

Although the present invention has been described with respect to certain specific embodiments, it will be clear to those skilled in the art that the inventive features of the present invention are applicable to other embodiments as well, all of which are intended to fall within the scope of the present invention.

1. A method for generating LED product groups utilized in solid state lighting devices that comply with user-defined LED color point and collective forward voltage and flux target properties utilizing a cloud of unbinned light emitting diode (LED) units, the method comprising:
testing in real time the unbinned LED units to determine light emitting properties of said unbinned LED units; and
assigning each said unbinned LED unit to an associated said LED product group based upon the determined light emitting properties of said each unbinned LED unit, and based upon calculated compliance of the associated said LED product group including said unbinned LED unit with calculated flexible group characteristics that are at least partially based on said user-defined LED color point and collective forward voltage and flux target properties.

2. The method of claim 1, further comprising:
initially calculating said flexible group characteristics using said user-defined LED color point and collective forward voltage and flux target properties; and
adjusting said flexible group characteristics in real time during the testing and assignment process based upon collective light emitting properties of the unbinned LED units which have been determined during initial stages of the testing and assignment process.

3. The method of claim 1, wherein assigning each said unbinned LED unit further comprises placing, in real time, said each unbinned LED unit either onto a carrier or into a parking lot.

4. The method according to claim 3, wherein placing said unbinned LED unit onto a carrier comprises mounting said unbinned LED unit onto one of a printed circuit board and a reel.

5. The method according to claim 1, wherein assigning said each unbinned LED unit to an associated said LED product group comprises determining that the targeted color coordinate tolerance of the associated LED product group having a given group size is more than three times smaller than a variation of x- and y- from amongst the plurality of unbinned LED units in the cloud.

6. The method according to claim 1, wherein the cloud comprises unbinned LED units that are contained within less than eight step MacAdam ellipses but exceed four MacAdam ellipses of variation in extent.

7. The method according to claim 6, wherein assigning comprises forming associated LED product groups comprising unbinned LED units contained within less than two MacAdam ellipses.

8. The method according to claim 1, further comprising utilizing a pick and place tool to place each unbinned LED unit onto a board immediately after assignment of said unbinned LED unit, where said board is populated only by unbinned LED units of said associated LED product group to which said unbinned LED unit is assigned.

9. The method according to claim 1, further comprising generating updated LED group information including a running total of the characteristics of the summation of die color coordinates of the unbinned LED units assigned to each said LED product group, and utilizing said updated LED group information for the calculation of optimum assignment of subsequently tested unbinned LED units.

10. The method according to claim 1, further comprising generating updated LED group information including a running total of the characteristics of the summation of die forward voltage of the unbinned LED units assigned to each said LED product group, and utilizing said updated LED group information for the calculation of optimum assignment of subsequently tested unbinned LED units.

11. The method according to claim 1, further comprising generating updated LED group information including a running total of the characteristics of the summation of die flux having been placed onto each board or reel is kept as data for the calculation of optimum placement of subsequent die onto the boards or reels available.

12. A method for achieving color consistency in solid state lighting devices that include multiple LED units, the method comprising:
setting target final color consistency coordinates and coordinate tolerances for LED product groups to be populated by unbinned LED units and mounted on corresponding boards, and determining a number of LEDs to be assigned to each said solid state lighting device that will comply with said target final color consistency coordinates and coordinate tolerances;
characterizing in sequence the color coordinate of each unbinned LED unit in a supply of unbinned LED units generated during a given manufacturing run; and
directly populating said boards with said characterized unbinned LED units such that each said unbinned LED unit is mounted on an associated board that optimally benefits, based on said target final color consistency coordinates and coordinate tolerances, from addition of said each unbinned LED unit based on its characterized color coordinate.

13. A system for producing solid state lighting devices using a production cloud including a plurality of unbinned light emitting diode (LED) units such that each said solid state lighting device includes an LED product group made up of multiple said unbinned LED units mounted on a board, and such that, during operation, the multiple said unbinned LED units collectively generate mixed light conforming with user-defined parameters, and having a color uniformity of three MacAdam ellipses or less, the system comprising:
an LED tester configured to apply test conditions to an LED-under-test, and to measure light emitted from the LED-under-test under said test conditions;
an LED product group assembler;
means for sequentially transporting said unbinned LED units to the LED tester, and from the LED tester to the LED group assembler; and
a controller configured to:
generate flexible group characteristics based on said user-defined parameters;
assign each said unbinned LED unit to an associated said LED product group in accordance with LED light measurements received from the LED tester for said each unbinned LED unit, said assignment being performed such that said associated LED product group complies with said flexible group characteristics; and
update said flexible group characteristics in accordance with said LED light measurements.

14. The system of claim 13,
wherein the controller is further configured to generate group assembly control data for said each unbinned LED unit according to said assignment, and
wherein said LED group assembler includes a sorting mechanism for placing each of said plurality of unbinned LED units into an associated product group configuration in accordance with said group assembly control data such that each said product group configuration contains only unbinned LED units assigned to a single product group.

15. The system of claim 13, wherein the controller is further configured to temporarily assign one or more of said unbinned LED units to a holding area when assigning said one or more of said unbinned LED units to said product group configurations fails to comply with said flexible group characteristics.

16. The system of claim 13, wherein each said unbinned LED unit includes an indium-gallium-nitride (InGaN) film and a phosphor layer formed on the InGaN film, and wherein the LED tester comprises:
a laser positioned to direct its light onto said LED-under-test, the laser configured to selectively heat portions of the phosphor layer;
a probe tester configured to apply current to the InGaN film of the LED to establish a predetermined junction temperature in the InGaN film and to provide electroluminescence;
an integrating sphere configured to collect light emitted by the LED during testing; and
a spectrometer system configured to perform photometric measurements on light collected by the integrating sphere.
